(19) United States
(12) Patent Application Publication
(10) Pub. No.: US 2009/0251192 A1
(43) Pub. Date: Oct. 8, 2009

(54) SELF-CALIBRATION CIRCUIT FOR USB CHIPS AND METHOD THEREOF

(76) Inventors: Keng Khai Ong, Hsin Chu County (TW); Yi-Jing Lin, Tai Pei County (TW)

Correspondence Address: Muncy, Geissler, Olds & Lowe, PLLC, P.O. BOX 1364, FAIRFAX, VA, 22038-1364, US

(21) Appl. No.: 12/417,350

(22) Filed: Apr. 2, 2009

(30) Foreign Application Priority Data
Apr. 3, 2008 (TW) 097112105

(51) Int. Cl. H03L 5/00

(52) U.S. Cl. 327/331

(57) ABSTRACT

A USB chip having a self-calibration circuit is provided. The USB chip includes a comparing circuit, a digital circuit and an adjustable current output device. A close-loop structure is provided to monitor an output voltage level of the USB chip and then an output current is dynamically adjusted to calibrate the output voltage level.

This application claims the benefit of the filing date of Taiwan Application Ser. No. 097112105, filed on Apr. 3, 2008, the content of which is incorporated herein by reference.

### BACKGROUND OF THE INVENTION

1. Field of the Invention

The invention relates to integrated circuits, particularly to a universal serial bus (USB) chip having a self-calibration circuit and a calibration method, which are applied to high-speed USB 2.0 compliant devices.

2. Description of the Related Art

FIG. 1 is a timing diagram illustrating a USB 2.0 interface conducting a high-speed detection protocol. After a high-speed USB device is attached to a USB port of a host, there are generally five stages until the high-speed USB device establishes a high-speed communication with the host.

Stage one: idle state. After the high-speed USB device is attached to the USB port of the host, the 1.5K ohm pull-up resistor of the high-speed USB device pulls the voltage of a D+ line up to 3V, causing the host to detect a newly attached device.

Stage two: reset state. The host asserts a reset signal (SEO) to drive the D+ line and the D− line to ground for at least 2.5 μs.

Stage three: Chirp-K state. The high-speed USB device indicates its speed by pulling the D− line up to 800 mV. This creates a Chirp-K on the bus. The USB device chirp must last no less than 1 ms and must end no more than 7 ms.

Stage four: Chirp-J/K-1 state. No more than 100 μs after the bus leaves the Chirp-K state, a high-speed capable host begins to send an alternating sequence of Chirp-K's and Chirp-J's. At this moment, the high voltage levels of the D+ and D− lines are equal to 800 mV.

Stage five: Chirp-J/K-2 state. After detecting the sequence Chirp K-J-K-J-K-J, the high-speed USB device disconnects the D+pull-up resistor, enables the high speed terminations and operates in high-speed mode. At this moment, the high voltage levels of the D+ and D− lines are pulled down to 400 mV since the D+ and D− lines are respectively connected to pull-down resistors (45 ohm).

On the other hand, the USB 2.0 specification defines an output voltage (TX swing) of a USB device operating in high speed mode must be 400 mV±10% and suggests the use of the circuit in FIG. 2A to generate the output voltage. Referring to FIG. 2A, a constant current source I₁ (its current is 17.78 mA) and an internal termination resistor R_{IN} (its resistance value is 45 ohm) are built inside a USB device chip, whereas its output terminal DP/DM is coupled to an internal termination resistor R_{H} (its resistance value is 45 ohm) via a USB cable. The constant current source I₁ is implemented as follows. A bandgap reference circuit is used to provide a constant voltage (e.g., 1.2 V), independent of temperature and supply voltage. A combination of the constant voltage of 1.2 V, a transistor M₂ and an external resistor R_{EXT} (for example, the resistance value is 12K ohm) are used to generate a constant current I₂. Finally, the constant current source I₁ is obtained by means of a current mirror circuit consisting of transistor M₁ and M₂, as shown in FIG. 2B.

However, there are drawbacks or limitations in the circuits of FIGS. 2A and 2B. First, the USB device chip is required to have an additional IC pin Pₒᵤₜ. Secondly, the USB device chip is required to increase the hardware cost of passive elements, such as the external resistor R_{EXT}. Thirdly, the resistance variation of the termination resistor R_{H} in the host needs to be taken into consideration. Here, the former two issues belong to hardware cost; however, the third issue is restricted to variations of process, voltage and temperature (hereinafter called “PVT”) in the remote host. For example, assuming that the resistance value of the termination resistor R_{H} in the host is around the threshold value (45 ohm+10%) and the resistance value of the termination resistor R_{IN} in the device is shifted, the output voltage V_{DP}/V_{DM} of the device may fail to comply with the USB 2.0 standard.

In view of a problem of insufficient number of pins in the USB device chips, a growing trend is that the external resistors R_{EXT} is integrated into the USB device chip in order to increase competition in external hardware cost (a common USB chip generally has the following five pins: V_{DD}, GND, DP, DM and R_{EXT}) for related USB chips in the future. However, a critical yield rate problem will be encountered since semiconductor fabs can only assure a resistance precision of 15%. In order to reduce the resistance variation of the internal resistors caused by PVT variations, a calibration technique is required to be added into the USB device chip. In the prior, a calibration technique is applied to the USB device chip via a reserved trim pad of the bandgap reference circuit, thereby increasing the wafer sort cost. Accordingly, what is needed is a method and circuit to improve both efficiency and yield rate. The invention addresses such a need.

### SUMMARY OF THE INVENTION

In view of the above-mentioned problems, an object of the invention is to provide a USB chip having a self-calibration circuit, which uses a close-loop structure to dynamically modify the magnitude of an output current I₃ in accordance with an output voltage V_{DM} and calibrate the output voltage V_{DM} while connected with a termination resistor in a host.

To achieve the above-mentioned object, the invention provides a USB chip having a self-calibration circuit of the invention for calibrating a voltage of an output terminal of the USB chip, comprising: a comparing circuit for comparing a reference voltage with the voltage of the output terminal to generate a comparing result; a digital circuit for modifying an output value of the digital circuit according to the comparing result; and, an adjustable current output device for generating a first current at the output terminal according to the output value of the digital circuit; wherein when the USB chip is built in a USB device, the self-calibration circuit is activated during a period of a Chirp-K state while the USB chip handshakes with a host, and when the USB chip is built in a USB host, the self-calibration circuit is activated during a period of a Chirp-J/K-1 state or a Chirp-J/K-2 state while the USB chip handshakes with the USB device.

Another object of the invention is to provide a method for calibrating a voltage of an output terminal of a USB chip, comprising the steps of: comparing a reference voltage with the voltage of the output terminal to generate a comparing result; modifying an output value of a digital circuit according to the comparing result; and, generating a first magnitude of current at the output terminal according to the output value of the digital circuit; wherein when the USB chip is built in a USB device, the self-calibration circuit is activated during a period of a Chirp-K state while the USB chip handshakes with a host, and when the USB chip is built in a USB host, the self-calibration circuit is activated during a period of a Chirp-J/K-1 state or a Chirp-J/K-2 state while the USB chip handshakes with the USB device.

Further scope of the applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 is a timing diagram illustrating a USB 2.0 interface conducting a high-speed detection protocol.

FIG. 2A shows a diagram that a device is connected to a host via a USB 2.0 interface.

FIG. 2B shows a schematic circuit diagram of a conventional constant current source circuit.

FIG. 3 shows a schematic circuit diagram of a self-calibration circuit embedded in a USB chip according to an embodiment of the invention.

FIG. 4 shows a schematic circuit diagram of a self-calibration circuit embedded in a USB chip according to another embodiment of the invention.

FIG. 5A shows an exemplary voltage waveform measured at an output terminal DP/DM (the D+/D− lines) of the self-calibration circuit embedded in the USB chip at stage three according to the invention.

FIG. 5B shows another exemplary voltage waveform measured at the output terminal DP/DM of the self-calibration circuit embedded in the USB chip at stage three according to the invention.

FIG. 6 compares two simulation results of the prior art and the invention.

### DETAILED DESCRIPTION OF THE INVENTION

The invention takes high-speed USB devices as an example for explanation. However, a self-calibration circuit and method according to the invention can also be applied in other integrated circuits that need an output voltage calibration by modifying a corresponding output current.

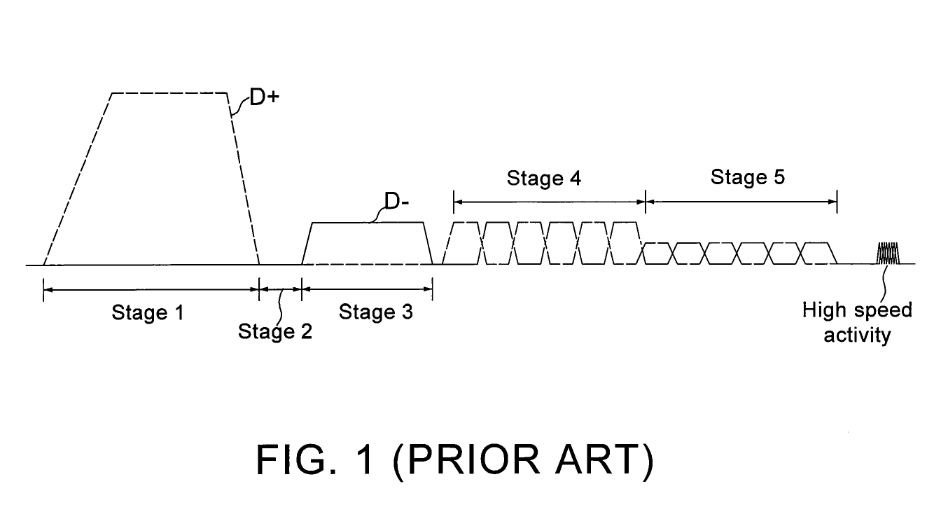

After a 12K-ohm resistor R_{EXT} is moved from external to internal, since PVT variations may cause the resistance variation of the internal resistors R_{EXT} and R_{IN} and therefore the output terminal may suffer from voltage level offset, the high-speed USB device chip needs a calibration mechanism for operations. As can be observed in FIG. 1, while the high-speed USB device handshakes with the host, the output voltage V_{DM} (i.e., the D− line) doesn't transition during the period (of 1 ms to 7 ms) of stage three. The self-calibration circuit according to the invention makes use of the period of stage three to modify the level of the output voltage V_{DM} for auto-calibration.

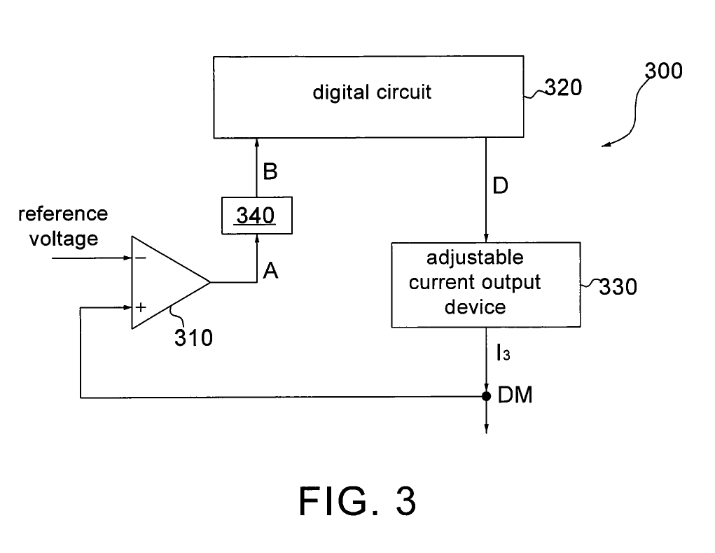

FIG. 3 shows a schematic circuit diagram of a self-calibration circuit embedded in a USB chip according to an embodiment of the invention. Referring to FIG. 3, a self-calibration circuit 300 embedded in a USB chip includes a comparator 310, an analog-to-digital converter (ADC) 340, a digital circuit 320 and an adjustable current output device 330. During the period of stage three as shown in FIG. 1, the comparator 310 compares the voltage V_{DM} of the output terminal with a reference voltage to generate an analog comparing result A. In this embodiment, the reference voltage is provided by a bandgap reference circuit.

The ADC 340 receives the comparing result A and then converts it into a digital signal B. According to the digital signal B, the digital circuit 320 checks the magnitude of current I₃ flowing through the output terminal and then determines whether to modify a digital control value D for output. Here, the digital circuit 320 can be implemented using a central processing unit (CPU) or a digital signal processor that already exists inside the USB chip, without increasing any hardware cost; instead, the digital circuit 320 can be implemented using an additional state machine, with little additional hardware cost. The implementation of the digital circuit 320 is well known to those skilled in the art and thus will not be described herein. Lastly, according to the control value D, the adjustable current output device 330 generates a corresponding magnitude of the output current I₃ flowing through the output terminal DM. This causes the output terminal DM to generate a corresponding output voltage V_{DM} and then the output voltage V_{DM} will be converged to the reference voltage (i.e., 800 mV). During the entire calibration operation, the self-calibration circuit 300 is always connected with the termination resistor R_{H} in the host to calibrate the final output voltage V_{DM}. In other words, according to the invention, the resistance variation of the termination resistor R_{H} in the host is calibrated as well.

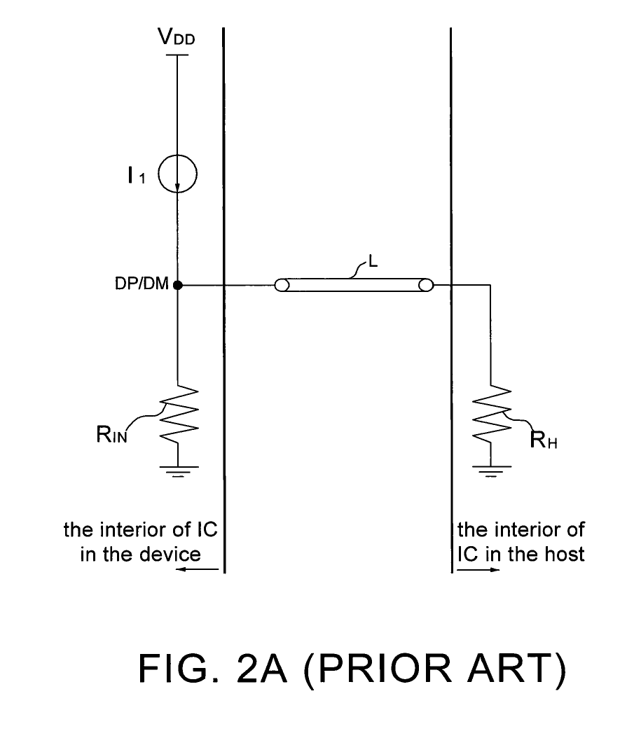

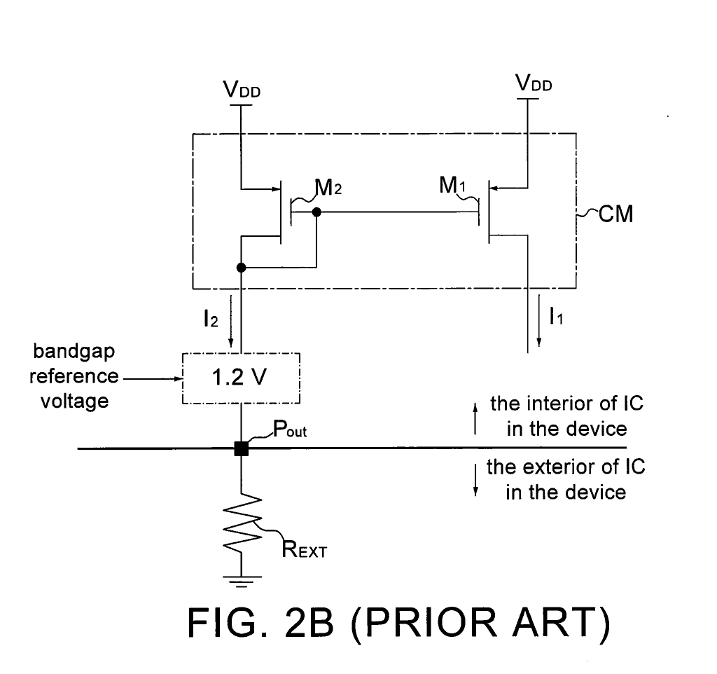

According to the embodiment, during the period of stage three, the output current I₃ is provided to generate a corresponding output voltage V_{DM} (approximately 800 mV), so the current mirror circuit CM in FIG. 2B is not needed any more. In conventional USB chips, based on a multiple-mirror structure, the current mirror circuit CM duplicates a reference current to form a large amount of current (i.e., 17.78 mA) for output. The current mirror circuit CM is implemented using a large number of transistors and subject to mirror mismatch, especially obvious in advanced manufacturing process. By comparison, the invention can not only solve the above-mentioned problem, but also uses a simple circuit structure to reduce layout complexity and raise yield rate. Further, the resistor R_{EXT} is moved from external to internal and the self-calibration circuit 300 of the invention performs self-calibration operations, thus reducing the effect of PVT on the internal resistors. Accordingly, a pin of the USB chip is saved, the cost of whole system is reduced and the flexibility of PCB layout is increased.

According to the invention, either a structure of a variable current source or a structure having a constant current source plus a variable current source is included in the adjustable current output device 330. Hereinafter, the adjustable current output device having a constant current source plus a variable current source will be described in detail.

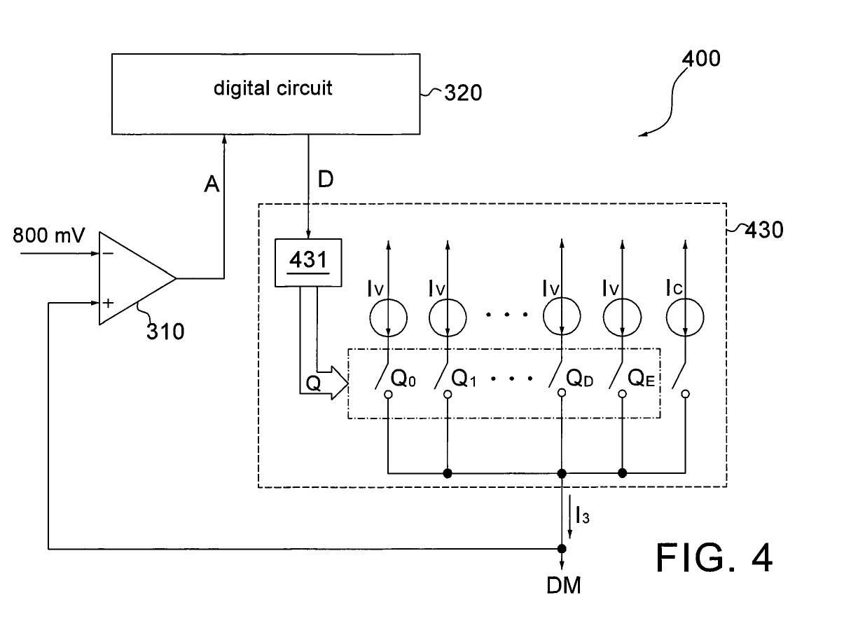

FIG. 4 shows a schematic circuit diagram of a self-calibration circuit embedded in a USB chip according to another embodiment of the invention. Referring to FIG. 4, a self-calibration circuit 400 embedded in a USB chip includes a comparator 310, a digital circuit 320 and an adjustable current output device 430. The differences between FIG. 3 and FIG. 4 are as follows. In the embodiment of FIG. 4, the self-calibration circuit 400 operates without the ADC 340 of FIG. 3 since there are only two different voltage levels (regarded as one-bit only) at the output terminal of the comparator 310. In addition, the adjustable current output device 430 includes a binary-to-thermometer decoder 431, a constant current source I_{C} and fifteen (2⁴⁻¹) identical current sources I_{V}.

As can be observed from the adjustable current output device 430 of FIG. 4, a variable current source part (a current in the range of 0 to 15 I_{V}) consists of fifteen identical current sources I_{V} and the binary-to-thermometer decoder 431. In fact, the adjustable current output device 430 is a structure of thermometer encoding current scaler. According to this embodiment, since the control value D is a binary code (i.e., a 4-bit data), the binary-to-thermometer decoder 431 is provided to convert the 4-bit binary code D into a hexadecimal thermometer code Q to control switches of the fifteen current sources lv.

In view of these two embodiments, a feature of the invention is that a close-loop structure is employed to monitor the output voltage V_{DM}. Once a voltage level offset occurs at the output terminal DM, the magnitude of the output current I₃ will be dynamically modified to pull the offset voltage V_{DM} in a normal range. Definitely, the variation range of the variable current source part needs to be able to cover process variation (normally 15%) of the internal resistor. Assuming that the constant current source I₃ generates a constant current of 15 mA and a total amount of current provided by the variable current source part is 6 mA (i.e., the magnitude of each current source I_{V} is 0.375 mA), the process variation will be covered up to 17% (=8×(0.375/17.78)). Further, the number of bits of the control value D can be increased to achieve a greater precision. It should be noted that in an alternative embodiment, based on a structure of a variable current source, the adjustable current output device includes a binary-to-thermometer decoder 431 and fifteen identical current sources I_{V}.

In addition to the thermometer encoding current scaler, the variable current source part of the adjustable current output device can be implemented using one of the following current scalers: a binary weighted current scaler, a two-step current scaler, a successive approximation current scaler and a R/2R current scaler. It should be understood, however, that the invention is not limited to the current scalers described above, but fully extensible to any existing or yet-to-be developed current scalers (as long as a magnitude of the output current I₃ is varied with the digital control value D). The implementation of the binary weighted current scaler, the two-step current scaler, the successive approximation current scaler and the R/2R current scaler is well known to those skilled in the art and thus will not be described herein.

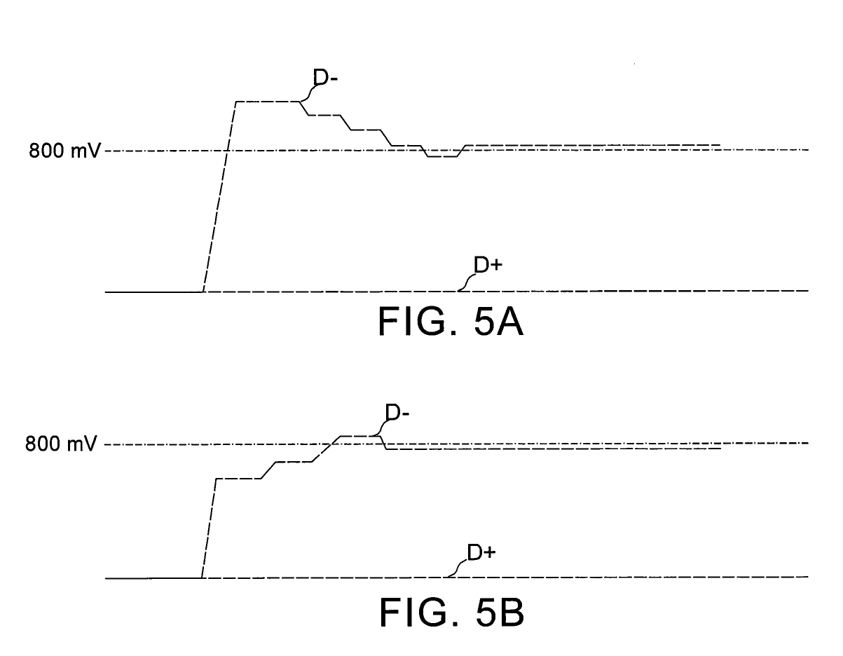

FIG. 5A shows an exemplary voltage waveform measured at an output terminal DP/DM (the D+/D− lines) of the self-calibration circuit embedded in the USB chip at stage three according to the invention. FIG. 5B shows another exemplary voltage waveform measured at the output terminal DP/DM of the self-calibration circuit embedded in the USB chip at stage three according to the invention. While entering stage three of high-speed detection handshake, a high-speed USB device having the self-calibration circuit of the invention generates an output voltage V_{DP}/V_{DM} with a waveform shown in FIG. 5A or FIG. 5B. FIG. 5A shows an example that an enormous amount of the output current I₃ at start-up results in a relatively high output voltage V_{DM} and then the output voltage V_{DM} goes down slowly. Contrarily, FIG. 5B shows an example that a small amount of the output current I₃ at start-up results in a relatively low output voltage V_{DM} and then the output voltage V_{DM} goes up steadily.

According to a test item on TX swing as specified in the USB-IF compliance test procedures, the bandgap reference voltage (3%), the 12K-ohm external resistor R_{EXT}(±1%), the built-in termination resistor R_{IN} (+10%) and the PV offset are four variation factors. Each of which affects the yield rate in the prior art. By adopting the self-calibration circuit of the invention, two variation factors of the 12K-ohm external resistor R_{EXT} and the PV offset are allowed to be modified by calibration. Only the other two variation factors of the bandgap reference voltage and the built-in termination resistor R_{IN} affect the yield rate. Therefore, the yield rate is significantly raised on the above-mentioned test item.

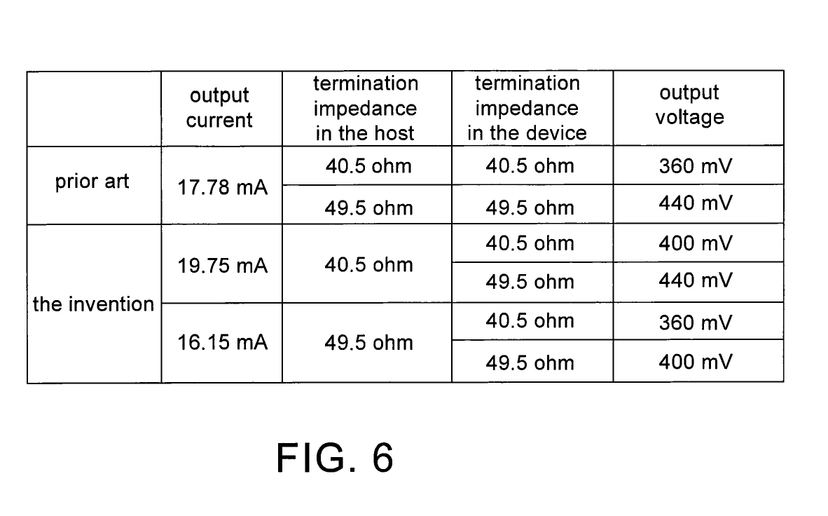

FIG. 6 compares two simulation results of the prior art and the invention. In practical applications, the timing of calibration for the USB chip having the self-calibration circuit of the invention is during the period that the high-speed USB device performs the high-speed detection handshakes with the host. Different hosts may provide termination resistors R_{H} with slightly different resistance values (45 ohm±10%) and the USB device has its internal resistor R_{IN} with variations in resistance, both of which affect the output voltage during high-speed transmission. The simulation results in FIG. 6 show that, if the output current I₃ is in the range of 16.15 mA to 19.75 mA (17.78 mA±10%) and both of the termination resistor R_{H} in the host and the termination resistor RN in the device is in the range of 40.5 ohm to 49.5 ohm (45 mA±10%), the output voltage of the high-speed USB device having the self-calibration circuit of the invention will be in the range of 360 mV to 440 mV (400 mV10%), fully complying with the USB 2.0 standard.

It should be understood that high-speed USB devices are taken as examples for explanation in the above-mentioned embodiments. A self-calibration circuit and method according to the invention can also be applied in USB host chips. However, according to the invention, the differences between a USB device chip having a self-calibration circuit and a USB host chip having a self-calibration circuit are as follows. A USB host chip having a self-calibration circuit of the invention is allowed to perform calibration operations during the period of either stage four or stage five. If the calibration operations are performed during the period of stage four, one of the voltages V_{DM} and V_{DP} of the output terminals (DM/DP) is compared with a reference voltage (i.e., the high voltage level at stage four: 800 mV) to generate the analog comparing result A in the comparator 310. On the other hand, if calibration operations are performed during the period of stage five, one of the voltages V_{DM} and V_{DP} of the output terminals (DM/DP) is compared with a reference voltage (i.e., the high voltage level at stage five: 400 mV) to generate the analog comparing result A in the comparator 310. Since the other operations and implementation of the self-calibration circuit embedded in the USB device chip are the same as those of the self-calibration circuit embedded in the USB host chip, the description is omitted here.

While certain exemplary embodiments have been described and shown in the accompanying drawings, it is to be understood that such embodiments are merely illustrative of and not restrictive on the broad invention, and that this invention should not be limited to the specific construction and arrangement shown and described, since various other modifications may occur to those ordinarily skilled in the art.

What is claimed is:

1. A USB chip having a self-calibration circuit, for calibrating a voltage of an output terminal of the USB chip, the USB chip comprising:
a comparing circuit, for comparing a reference voltage with the voltage of the output terminal to generate a comparing result;
a digital circuit, for modifying an output value of the digital circuit according to the comparing result; and
an adjustable current output device, for generating a first current at the output terminal according to the output value of the digital circuit;
wherein when the USB chip is built in a USB device, the self-calibration circuit is activated during a period of a Chirp-K state while the USB chip handshakes with a host, and when the USB chip is built in a USB host, the self-calibration circuit is activated during a period of a Chirp-J/K-1 state or a Chirp-J/K-2 state while the USB chip handshakes with the USB device.

2. The USB chip according to claim 1, wherein the USB chip supports USB 2.0 interface.

3. The USB chip according to claim 2, wherein when the USB chip is built in the USB device, the output terminal is at a D− line (DM).

4. The USB chip according to claim 2, wherein when the USB chip is built in the USB device, the reference voltage is at a first voltage level.

5. The USB chip according to claim 2, wherein when the USB chip is built in the USB host, the output terminal is at a D− line (DM) or a D+ line (DP).

6. The USB chip according to claim 2, wherein when the USB chip is built in the USB host, the reference voltage is at a first voltage level if the self-calibration circuit is activated during the period of the Chirp-J/K-1 state.

7. The USB chip according to claim 6, wherein when the USB chip is built in the USB host, the reference voltage is at a second voltage level if the self-calibration circuit is activated during the period of the Chirp-J/K-2 state and the first voltage level is greater than the second voltage level.

8. The USB chip according to claim 1, wherein the reference voltage is provided by a bandgap reference circuit.

9. The USB chip according to claim 1, further comprising:
an analog-to-digital converter, coupled between the comparing circuit and the digital circuit, for converting the comparing result into a digital signal to be delivered to the digital circuit.

10. The USB chip according to claim 1, wherein the adjustable current output device is a binary weighted current scaler, a thermometer encoding current scaler, a two-step current scaler or a R/2R current scaler.

11. The USB chip according to claim 1, wherein the adjustable current output device comprises:
a variable current source, for generating the first current according to the output value of the digital circuit.

12. The USB chip according to claim 1, wherein the adjustable current output device comprises:
a constant current source, for generating a second current; and
a variable current source, for generating a third current according to the output value of the digital circuit;
wherein the first current is equal to the second current plus the third current.

13. The USB chip according to claim 12, wherein the variable current source comprises:
(2^{N}−1) identical switchable current sources; and
a binary-to-thermometer decoder, for converting the output value of the digital circuit into a hexadecimal thermometer code to control the (2^{N}−1) identical switchable current sources respectively;
wherein N is the bit width of the output value of the digital circuit and the total output current outputted from the (2^{N-1}) identical switchable current sources is equal to the third current.

14. A method for calibrating a voltage of an output terminal of a USB chip, comprising the steps of:
comparing a reference voltage with the voltage of the output terminal to generate a comparing result;
modifying an output value of a digital circuit according to the comparing result; and
generating a first current at the output terminal according to the output value of the digital circuit;
wherein when the USB chip is built in a USB device, the self-calibration circuit is activated during a period of a Chirp-K state while the USB chip handshakes with a host, and when the USB chip is built in a USB host, the self-calibration circuit is activated during a period of a Chirp-J/K-1 state or a Chirp-J/K-2 state while the USB chip handshakes with the USB device.

15. The method according to claim 14, wherein when the USB chip is built in the USB device, the output terminal is at a D− line (DM).

16. The method according to claim 15, wherein the reference voltage is at a first voltage level.

17. The method according to claim 14, wherein when the USB chip is built in the USB host, the output terminal is at a D− line (DM) or a D+ line (DP).

18. The method according to claim 17, wherein the reference voltage is at a first voltage level if the method is employed during the period of the Chirp-J/K-2 state.

19. The method according to claim 18, wherein the reference voltage is at a second voltage level if the method is employed during the period of the Chirp-J/K-2 state and the first voltage level is greater than the second voltage level.

20. The method according to claim 14, wherein the step of generating the first current further comprises:
generating a second current by using a constant current source; and
generating a third current at the output terminal by using a variable current source according to the output value of the digital circuit;
wherein the first current is equal to the second current plus the third current.
